(19) United States
(12) Patent Application Publication
(10) Pub. No.: US 2023/0209945 A1
(43) Pub. Date: Jun. 29, 2023

(54) DISPLAY DEVICE AND METHOD FOR MANUFACTURING THE SAME

(71) Applicant: LG DISPLAY CO., LTD., Seoul (KR)

(72) Inventor: JeongHyeon CHOI, Seoul (KR)

(73) Assignee: LG DISPLAY CO., LTD., SEOUL (KR)

(21) Appl. No.: 17/981,353

(22) Filed: Nov. 4, 2022

(30) Foreign Application Priority Data
Dec. 27, 2021 (KR) 10-2021-0188961

(51) Int. Cl. H01L 27/32

(52) U.S. Cl. CPC H01L 27/3213; H01L 27/322; H01L 27/3246; H01L 27/3272; H01L 2227/323

(57) ABSTRACT

A display device and a method for manufacturing the same which can mitigate moisture permeability and dark spots by comprising a substrate, a pixel area including two or more subpixels on the substrate, and of the pixel area, a first subpixel area where a color filter is positioned and a second subpixel area adjacent to the first subpixel area are disposed, a first overcoat layer and a second overcoat layer disconnected between the first subpixel area and the second subpixel area, the first overcoat layer and the second overcoat layer positioned in the first subpixel area and the second subpixel area, respectively, and a first bank layer positioned at a boundary of the first subpixel area and a second bank layer positioned at a boundary of the second subpixel area, wherein the first bank layer and the second overcoat layer include an overlapping portion where the first bank layer and the second overcoat layer overlap with each other on the color filter.

### CROSS-REFERENCE TO RELATED APPLICATION

This application claims the priority of Korean Patent Application No. 10-2021-0188961, filed on Dec. 27, 2021, which is hereby incorporated by reference in its entirety.

### BACKGROUND

### Field of the Present Disclosure

The present disclosure relates to a display device and a method for manufacturing the same.

### Description of the Background

The growth of information society leads to various needs for displays and wide use of various forms of displays, such as liquid crystal displays (LCDs), plasma display panels (PDPs), or organic light emitting diode displays (OLEDs). Such a display device includes a display panel fit therefor.

A display panel has a plurality of pixels which may be divided into red, green, blue, and white subpixels. The subpixels may use a color filter that limits a specific wavelength of light or shifts a wavelength band of light for each subpixel to implement a color. Each subpixel may also emit light. A light leak in two or more colors may occur depending on whether the subpixel emits light or the degree of emission, degrading the viewing angle. Therefore, a need exists for technology for blocking off light leakage in the subpixel.

In the organic light emitting display device, slits are formed in the overcoat layer to enhance the viewing angle. However, due to degradation of the uniformity of the slits in the overcoat layer throughout the display panel, the overcoat layer and the bank layer in the periphery of the display panel fail to completely cover the color filters, causing moisture permeability and dark spots in the area where the light emitting layer and the color filter contact each other.

### SUMMARY

Accordingly, the present disclosure is to provide a display device and a method for manufacturing the same which may mitigate moisture permeability and dark spots and make the viewing angle uniform over the entire display panel by forming a structure in which the overcoat layer and the bank layer overlap with and cover the color filter to prevent the light emitting layer from contacting the color filter to enhance the uniformity of the slits in the overcoat layer throughout the display panel.

Various aspects of the present disclosure provides a display device and a method for manufacturing the same which may mitigate moisture permeability and dark spots and make the viewing angle uniform over the entire display panel.

In an aspect of the present disclosure, a display device includes a substrate, a pixel area including two or more subpixels on the substrate, and of the pixel area, a first subpixel area where a color filter is positioned and a second subpixel area adjacent to the first subpixel area are disposed, a first overcoat layer and a second overcoat layer disconnected between the first subpixel area and the second subpixel area, the first overcoat layer and the second overcoat layer positioned in the first subpixel area and the second subpixel area, respectively, and a first bank layer positioned at a boundary of the first subpixel area and a second bank layer positioned at a boundary of the second subpixel area, wherein the first bank layer and the second overcoat layer include an overlapping portion where the first bank layer and the second overcoat layer overlap with each other on the color filter.

In another aspect of the present disclosure, a method for manufacturing a display device includes forming a color filter in a subpixel area constituting a pixel area on a substrate, forming an overcoat layer on the color filter to be disconnected at a boundary of the subpixel area, forming a first electrode on the overcoat layer, forming a bank layer on a boundary of the overcoat layer, and forming a light emitting layer on the bank layer and the overcoat layer, wherein forming the bank layer includes forming an overlapping portion where a first bank layer in a first subpixel area and a second overcoat layer in a second subpixel area overlap with each other on the color filter.

According to various aspects of the present disclosure, a display device and a method for manufacturing the same can mitigate moisture permeability and dark spots and make the viewing angle uniform over the entire display panel by forming a structure in which the overcoat layer and the bank layer overlap with and cover the color filter to prevent the light emitting layer from contacting the color filter by enhancing the uniformity of the slits in the overcoat layer throughout the display panel.

### BRIEF DESCRIPTION OF THE DRAWINGS

The above and other features and advantages of the present disclosure will be more clearly understood from the following detailed description, taken in conjunction with the accompanying drawings, in which:

FIG. 1 is a view illustrating a system configuration of a display device according to aspects of the present disclosure;

FIG. 2 is a plan view schematically illustrating a display panel according to aspects of the present disclosure;

FIGS. 3A and 3B are views illustrating moisture permeation and a dark spot in a display panel and pixel;

FIGS. 4A and 4B are views illustrating contact, as a defect, between a light emitting layer and a color filter, which occurs between subpixels;

FIG. 5 is a cross-sectional view taken along line B-B′ of FIG. 2;

FIG. 6 is a view schematically illustrating a compensation design of an overcoat layer slit according to aspects of the present disclosure;

FIG. 7 is a cross-sectional view taken along line B-B′ of FIG. 2 illustrating another example of a display device according to aspects of the present disclosure; and

FIGS. 8A, 8B, 8C, 8D, 8E, 8F, 8G, 8H, 8I, and 8J are views illustrating a process of forming a light blocking member on a color filter according to aspects of the present disclosure.

### DETAILED DESCRIPTION

In the following description of examples or aspects of the present disclosure, reference will be made to the accompanying drawings in which it is shown by way of illustration specific examples or aspects that can be implemented, and in which the same reference numerals and signs can be used to designate the same or like components even when they are shown in different accompanying drawings from one another. Further, in the following description of examples or aspects of the present disclosure, detailed descriptions of well-known functions and components incorporated herein will be omitted when it is determined that the description may make the subject matter in some aspects of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various aspects of the present disclosure are described in detail with reference to the accompanying drawings.

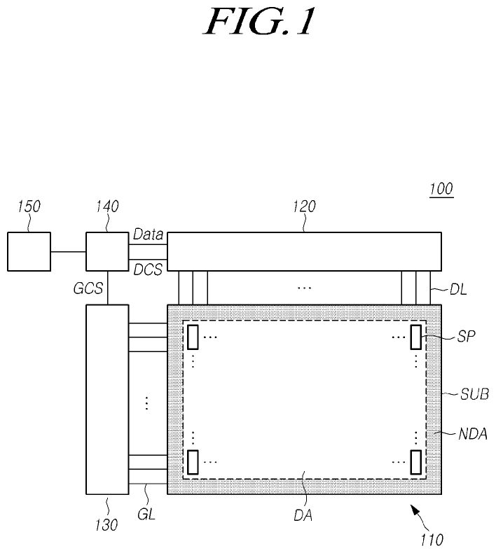

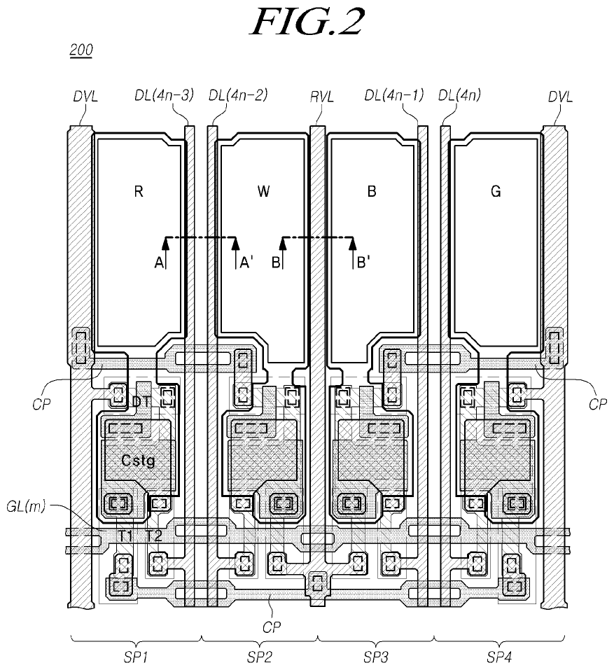

FIG. 1 is a view illustrating a system configuration of a display device according to aspects of the present disclosure. FIG. 2 is a plan view schematically illustrating a display panel according to aspects of the present disclosure.

Referring to FIG. 1, a display device 100 according to aspects of the present disclosure may include a display panel 110 and driving circuits for driving the display panel 110.

The driving circuits may include a data driving circuit 120 and a gate driving circuit 130. The display device 100 may further include a controller 140 controlling the data driving circuit 120 and the gate driving circuit 130.

The display panel 110 may include a substrate SUB and signal lines, such as a plurality of data lines DL and a plurality of gate lines GL disposed on the substrate SUB. The display panel 110 may include a plurality of subpixels SP connected to the plurality of data lines DL and the plurality of gate lines GL.

The display panel 110 may include a display area DA in which images are displayed and a non-display area NDA in which no image is displayed. In the display panel 110, a plurality of subpixels SP for displaying images may be disposed in the display area DA, and the data driving circuit 120, the gate driving circuit 130, and the controller 140 may be electrically connected or disposed in the non-display area NDA. Further, pad units for connection of integrated circuits or a printed circuit may be disposed in the non-display area NA.

The data driving circuit 120 is a circuit for driving the plurality of data lines DL, and may supply data signals to the plurality of data lines DL. The gate driving circuit 130 is a circuit for driving the plurality of gate lines GL, and may supply gate signals to the plurality of gate lines GL. The controller 140 may supply a data control signal DCS to the data driving circuit 120 to control the operation timing of the data driving circuit 120. The controller 140 may supply a gate control signal GCS for controlling the operation timing of the gate driving circuit 130 to the gate driving circuit 130.

The controller 140 may start scanning according to a timing implemented in each frame, convert input image data input from the outside into image data Data suited for the data signal format used in the data driving circuit 120, supply the image data Data to the data driving circuit 120, and control data driving at an appropriate time suited for scanning.

To control the gate driving circuit 130, the controller 140 may output various gate control signals GCS including a gate start pulse GSP, a gate shift clock GSC, and a gate output enable signal (Gate Output Enable, GOE).

To control the data driving circuit 120, the controller 140 may output various data control signals DCS including, e.g., a source start pulse SSP, a source sampling clock SSC, and a source output enable signal SOE.

The controller 140 may be implemented as a separate component from the data driving circuit 120, or the controller 140, along with the data driving circuit 120, may be implemented as an integrated circuit.

The data driving circuit 120 receives the image data Data from the controller 140 and supply data voltages to the plurality of data lines DL, thereby driving the plurality of data lines DL. The data driving circuit 120 is also referred to as a ‘source driving circuit.’

The data driving circuit 120 may include one or more source driver integrated circuit (SDICs).

For example, each source driver integrated circuit (SDIC) may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit 130 may output a gate signal of a turn-on level voltage or a gate signal of a turn-off level voltage according to the control of the controller 140. The gate driving circuit 130 may sequentially drive the plurality of gate lines GL by sequentially supplying gate signals of the turn-on level voltage to the plurality of gate lines GL.

The gate driving circuit 130 may be connected with the display panel 110 by TAB method or connected to a bonding pad of the display panel 110 by a COG or COP method or may be connected with the display panel 110 according to a COF method. Alternatively, the gate driving circuit 130 may be formed in a gate in panel (GIP) type, in the non-display area NDA of the display panel 110. The gate driving circuit 130 may be disposed on the substrate SUB or may be connected to the substrate SUB. In other words, the gate driving circuit 130 that is of a GIP type may be disposed in the non-display area NDA of the substrate SUB. The gate driving circuit 130 that is of a chip-on-glass (COG) type or chip-on-film (COF) type may be connected to the substrate SUB.

Meanwhile, at least one of the data driving circuit 120 and the gate driving circuit 130 may be disposed in the display area DA. For example, at least one of the data driving circuit 120 and the gate driving circuit 130 may be disposed not to overlap with the subpixels SP or to overlap with all or some of the subpixels SP.

When a specific gate line GL is opened by the gate driving circuit 130, the data driving circuit 120 may convert the image data Data received from the controller 140 into an analog data voltage and supply it to the plurality of data lines DL.

The data driving circuit 120 may be connected to one side (e.g., an upper or lower side) of the display panel 110. Depending on the driving scheme or the panel design scheme, data driving circuits 120 may be connected with both the sides (e.g., both the upper and lower sides) of the display panel 110, or two or more of the four sides of the display panel 110.

The gate driving circuit 130 may be connected to one side (e.g., a left or right side) of the display panel 110. Depending on the driving scheme or the panel design scheme, gate driving circuits 130 may be connected with both the sides (e.g., both the left and right sides) of the display panel 110, or two or more of the four sides of the display panel 110.

The controller 140 may be a timing controller used in typical display technology, a control device that may perform other control functions as well as the functions of the timing controller, or a control device other than the timing controller, or may be a circuit in the control device. The controller 140 may be implemented as various circuits or electronic components, such as an integrated circuit (IC), a field programmable gate array (FPGA), an application specific integrated circuit (ASIC), or a processor.

The controller 140 may be mounted on a printed circuit board or a flexible printed circuit and may be electrically connected with the data driving circuit 120 and the gate driving circuit 130 through the printed circuit board or the flexible printed circuit.

The display device 100 according to aspects of the present disclosure may be a display including a backlight unit, such as a liquid crystal display, or may be a self-emission display, such as an organic light emitting diode (OLED) display, a quantum dot display, or a micro light emitting diode (LED) display.

If the display device 100 according to aspects of the present disclosure is an OLED display, each subpixel SP may include an organic light emitting diode (OLED), which by itself emits light, as the light emitting element. If the display device 100 according to aspects of the present disclosure is a quantum dot display, each subpixel SP may include a light emitting element formed of a quantum dot, which is a self-luminous semiconductor crystal. If the display device 100 according to aspects of the present disclosure is a micro LED display, each subpixel SP may include a micro LED, which is self-emissive and formed of an inorganic material, as the light emitting element.

When the display device 100 according to aspects of the present disclosure is an OLED display, each subpixel SP disposed on the display panel 110 may include circuit elements, such as an organic light emitting diode OLED, two or more transistors, and at least one capacitor.

The type and number of circuit elements constituting each subpixel may be varied depending on functions to be provided and design schemes.

Each subpixel in the display panel 110 according to aspects of the present disclosure may have a circuit structure for compensating for subpixel characteristic values, such as the characteristic values (e.g., threshold voltage) of the organic light emitting diode OLED and the characteristic values (e.g., threshold voltage and mobility) of the driving transistor for driving the organic light emitting diode OLED.

Referring to FIGS. 1 and 2, each subpixel SP is connected to one data line DL and receives only one scan signal SCAN through one gate line GL.

As illustrated in FIG. 2, each subpixel includes an organic light emitting diode OLED, a driving transistor DT, a first transistor T1, a second transistor T2, and a storage capacitor Cstg. As such, since each subpixel includes three transistors DT, T1, and T2 and one storage capacitor Cstg, each subpixel is said to have a 3T (Transistor) 1C (Capacitor) structure.

The first transistor T1 is controlled by the scan signal SCAN supplied from the gate line GL and is connected between a reference voltage line RVL that supplies a reference voltage Vref or a connection pattern CP connected to the reference voltage line RVL and the driving transistor DT. This first transistor T1 is also referred to as a “sensor transistor”.

The second transistor T2 is controlled by the scan signal SCAN commonly supplied from the gate line GL and is connected between the corresponding data line DL and the driving transistor DT. The second transistor T2 is also referred to as a “switching transistor”.

As mentioned above, the first transistor T1 and the second transistor T2 are controlled by one scan signal supplied through one same gate line (common gate line). As such, since each subpixel uses one scan signal, it is said that each subpixel has a default subpixel structure of “3T1C-based one-scan structure” in aspects of the present disclosure.

However, without limitations thereto, the gate line and the sensing line may be individually connected to the first transistor T1 and the second transistor T2, and such a structure is referred to as a “3 T1C-based two-scan structure”.

The subpixel structure of the organic light emitting diode display 100 according to aspects of the present disclosure includes, in addition to the “default subpixel structure (3T1C-based one-scan structure)” described with reference to FIG. 2, a “signal line connection structure” which is related to connection of each subpixel to several signal lines, such as the data line DL, gate line GL, driving voltage line DVL, and reference voltage line RVL.

The signal lines may include not only the data line DL for supplying the data voltage to each subpixel and the gate line GL for supplying the scan signal but also a reference voltage line RVL for supplying the reference voltage Vref to each subpixel and a driving voltage line DVL for supplying the driving voltage EVDD.

In the present disclosure and drawings, the subpixel connected to the 4n-3th data line DL(4n-3), the subpixel connected to the 4n-2th data line DL(4n-2), the subpixel connected to the 4n-1th data line DL(4n-1), and the subpixel connected to the 4nth data line DL(4n) may be, e.g., a red (R) subpixel, a white (W) subpixel, a blue (W) subpixel, and a green (G) subpixel, respectively.

However, without limitations thereto, the red (R) subpixel, the white (W) subpixel, the blue (B) subpixel, and the green (G) subpixel may be arranged in other various orders. A pixel structure having the order of the red (R) subpixel SP1, the white (W) subpixel SP2, the blue (B) subpixel SP3, and the green (G) subpixel SP4 is described below.

As described above, when the default unit of the signal line connection structure includes four subpixels SP1 to SP4 connected to four data lines DL(4n-3), DL(4n-2), DL(4n-1), and DL(4n), one reference voltage line RVL for supplying the reference voltage Vref and two driving voltage lines DVL for supplying the driving voltage EVDD may be formed for the four subpixels SP1 to SP4. The four data lines DL(4n-3), DL(4n-2), DL(4n-1), and DL(4n) are connected to the four subpixels SP1 to SP4, respectively. Further, one gate line GL(m) (where 1≤m≤M) is connected to the four subpixels SP1 to SP4.

In the display device 100 according to aspects of the present disclosure, the organic light emitting diode OLED emitting white (W) light is commonly disposed in each subpixel, and a red (R) color filter, a blue (B) color filter, and a green (G) color filter are disposed in the red (R) subpixel SP1, the blue (B) subpixel SP3, and the green (G) subpixel SP4, respectively. No separate color filter is disposed in the white (W) subpixel SP2.

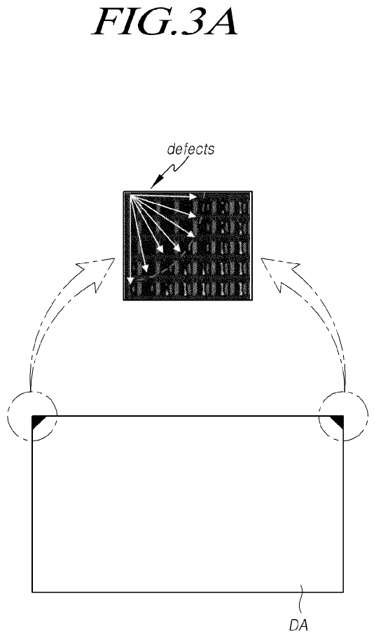

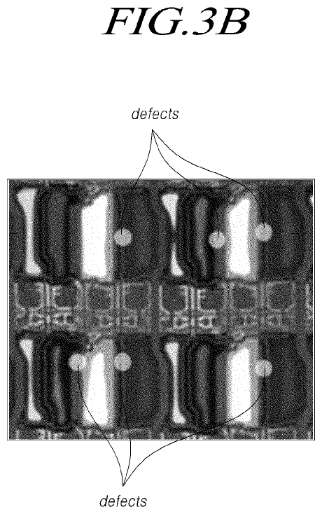

FIGS. 3A and 3B are views illustrating moisture permeation and a dark spot in a display panel and pixel.

In the organic light emitting diode display, each subpixel also emits light, and light leakage occurs between adjacent subpixels depending on whether light is emitted or the degree of light emission, thereby degrading the viewing angle. To enhance the viewing angle against light leakage between subpixels, a slit structure is introduced in the overcoat layer by removing the overcoat layer and the bank layer, which are layers playing a role as a light path, between the pigment of the color filter and the cathode electrode.

The slit structure of the overcoat layer is formed between the red (R) subpixel SP1 and the white (W) subpixel SP2 and between the white (W) subpixel SP2 and the blue (B) subpixel SP3.

The slit structure of the overcoat layer is formed by the same mask over the entire display panel. However, since the thickness of the overcoat layer at the periphery of the display panel is relatively small as compared to the inside, the slit uniformity of the overcoat layer may be deteriorated due to the difference in thickness of the overcoat layer although photolithography and ashing are performed under the same conditions, causing an excessive slit spacing in the overcoat layer at the periphery of the display panel.

The excessive slit spacing in the overcoat layer results in failure to sufficiently cover the color filter by the overcoat layer and bank layer, so that the color filter may be opened and contact the light emitting layer formed subsequently, causing moisture permeation and dark spots.

Referring to FIGS. 3A and 3B, moisture permeation and dark spots occur at the outer edge of the display panel and also in the pixel, e.g., between the red (R) subpixel SP1 and the white (W) subpixel SP2 and between the white (W) subpixel SP2 and the blue (B) subpixel SP3.

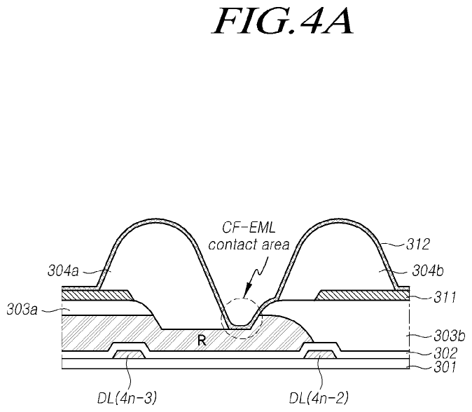

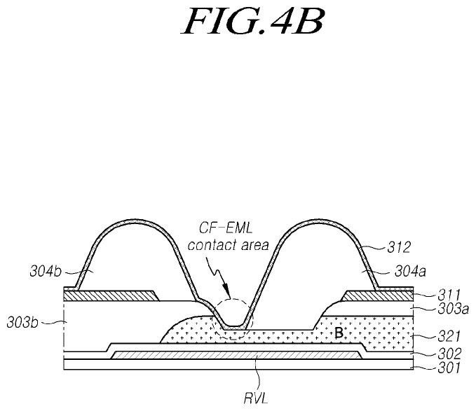

FIGS. 4A and 4B are views illustrating contact, as a defect, between the light emitting layer and the color filter which occurs between subpixels and respectively correspond to the cross-sectional views taken along A-A′ and B-B′ of FIG. 2.

Referring to FIGS. 4A and 4B, a first overcoat layer 303a and a first bank layer 304a are disposed in the first subpixel areas SP1 and SP3 where the color filters R and B are positioned, and a second overcoat layer 303b and a second bank layer 304b are disposed in the second subpixel area SP2 adjacent to the first subpixel areas SP1 and SP3.

The first overcoat layer 303a and the second overcoat layer 303b are disconnected to form a slit. Due to the excessive slit spacing between the first overcoat layer 303a and the second overcoat layer 303b, the first overcoat layer 303a and the first bank layer 304a, and the second overcoat layer 303b and the second bank layer 304a do not sufficiently cover the color filters R and B, causing the color filters R and B to be opened to directly contact the light emitting layer 312.

Since the pigments of the color filters R and B come into direct contact with the light emitting layer 312, moisture permeation and dark spots occur.

In the display device 100 according to aspects of the present disclosure, it is possible to mitigate moisture permeability and dark spots and make the viewing angle uniform over the entire display panel by forming a structure in which the overcoat layer and the bank layer overlap with and cover the color filter to prevent the light emitting layer from contacting the color filter to enhance the uniformity of the slits in the overcoat layer throughout the display panel.

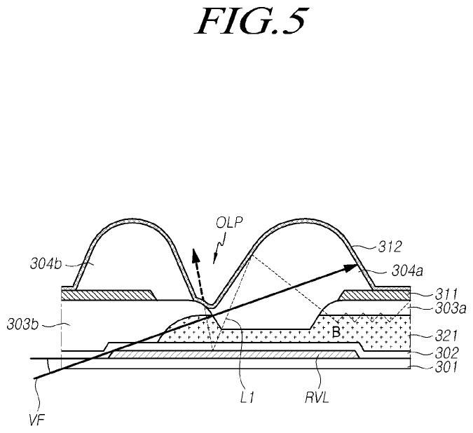

FIG. 5 is a cross-sectional view taken along line B-B′ of FIG. 2.

Referring to FIG. 5, in the display device 100 according to aspects of the present disclosure, a pixel area including two or more subpixels is disposed on a substrate and, of the pixel area, a first subpixel area where the color filter is positioned and a second subpixel area adjacent to the first subpixel area are disposed.

The first subpixel area may be any one of red (R), blue (B), and green (G) subpixels, and the second subpixel area may be a white (W) subpixel.

The display device 100 according to aspects of the present disclosure may be of a top emission type or a bottom emission type, but a bottom emission type of display device is described herein. According to aspects of the present disclosure, an organic light emitting diode emitting white (W) light may be commonly disposed in each of the subpixels SP1 to SP4, and color filters may be disposed in the areas of the red (R), blue (B), and green (G) subpixels SP1, SP3, and SP4. A structure in which the blue (B) color filter is disposed is described herein.

The blue (B) color filter may be disposed on the passivation film 302. However, without limitations thereto, a color filter may be formed between the inter-layer insulation film (not shown) and the buffer layer (not shown), between the buffer layer and the substrate 301, or between the inter-layer insulation film and the passivation film 302.

A first overcoat layer 303a and a first bank layer 304a may be positioned in the first subpixel area, and the first bank layer 304a may be disposed to be positioned at the boundary of the first subpixel area. A second overcoat layer 303b and a second bank layer 304b may be positioned in the second subpixel area, and the second bank layer 304b may be disposed to be positioned at the boundary of the second subpixel area.

The first overcoat layer 303a and the second overcoat layer 303b may be disposed to be disconnected between the first subpixel area and the second subpixel area, and the disconnected area between the first overcoat layer 303a and the second overcoat layer 303b may be positioned in the area of the first bank layer 304a.

The boundary between the first bank layer 304a and the second bank layer 304b may be positioned in the area of the second overcoat layer 303b.

The first bank layer 304a and the second overcoat layer 303b may include an overlapping portion OLP where they overlap with each other on the color filter. In the overlapping portion OLP, the first bank layer 304a and the second overcoat layer 303b may contact and overlap with each other.

As the overlapping portion OLP, where the first bank layer 304a and the second overcoat layer 303b overlap with each other, is positioned on the color filter, the color filter may be completely covered, so that even when the light emitting layer 312 is formed later, contact between the light emitting layer 312 and the color filter is prevented, mitigating moisture permeability and dark spots and enhancing the viewing angle VF over the entire display panel.

In the display device 100 according to aspects of the present disclosure, the first electrode 311 is a pixel electrode serving as an anode, and is independently disposed in each of the subpixels SP1 to SP4. The first electrode 211 is disposed between the overcoat layers 303a and 303b and the bank layers 304a and 304b for partitioning the subpixels SP1 to SP4.

The first electrode 311 may be formed of a metal, an alloy thereof, or a combination of a metal and a metal oxide, and the metal may be a transparent conductive material because the bottom emission is adopted. The first electrode 311 may be formed of one of ITO, IZO, ITO/APC/ITO, AlNd/ITO, Ag/ITO, and ITO/APC/ITO.

The light emitting layer 312 may be formed in a multi-layer structure including a hole injection layer, a hole transport layer, an emitting material layer, an electron transport layer, and an electron injection layer to increase light emission efficiency.

A second electrode (not shown) is formed on the light emitting layer 312.

In the display device according to aspects of the present disclosure, the description focuses primarily on an example where the first electrode 311 is an anode electrode and the second electrode is a cathode electrode. However, the present disclosure is not limited thereto but may also apply an example where the first electrode 250 is a cathode electrode and the second electrode 280 is an anode electrode.

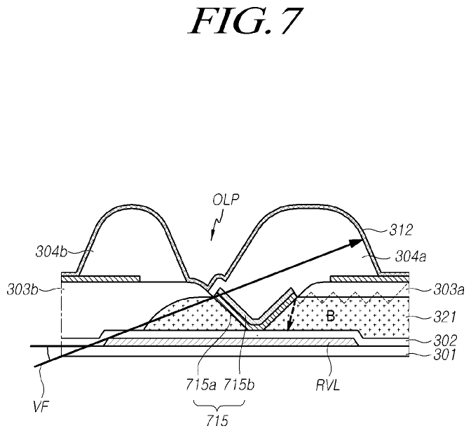

FIG. 7 is a cross-sectional view taken along line B-B′ of FIG. 2 illustrating another example of a display device according to aspects of the present disclosure.

Substantially the same description given for the foregoing aspects may be applied to the substrate 301, the protection layer 302, the first overcoat layer 303a, the first bank layer 304a, the second overcoat layer 303b, the second bank layer 304b, the overlapping portion OLP, the first electrode 311, and the light emitting layer 312 in FIG. 7.

Referring to FIG. 7, the display device 100 according to aspects of the present disclosure may be disposed to include a light blocking member 715 on the color filter. The color filter may include an area disconnected between the first overcoat layer 303a and the second overcoat layer 303b.

The light blocking member 715 may include a first electrode 311. The light blocking member 715 may be disposed in the disconnected area of the color filter.

The light blocking member 715 may have a double-layer structure of a first layer 715b and a second layer 715a. The first layer may be formed of a metal-based material, such as Cu, Al, Mo, MoTi, Ag, or Au. The second layer 715a may be formed of the above-described first electrode.

As the light blocking member 715 is disposed on the color filter, it is possible to prevent the light generated in the blue (B) subpixel area from being reflected by the light blocking member 715 to the white (W) pixel area. As the overlapping portion OLP is positioned on the color filter, the color filter may be completely covered, preventing contact between the light emitting layer 312 and the color filter, with the result of mitigating moisture permeability and dark spots and allowing for uniform viewing angle VF over the entire display panel.

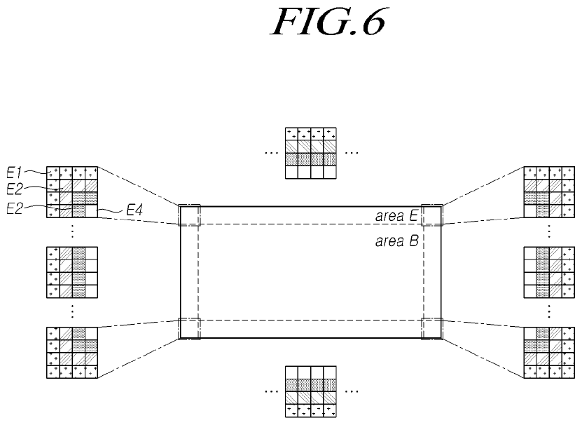

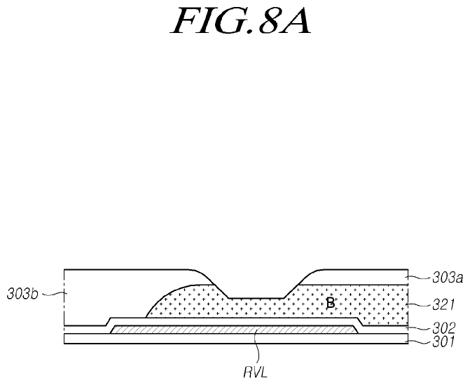

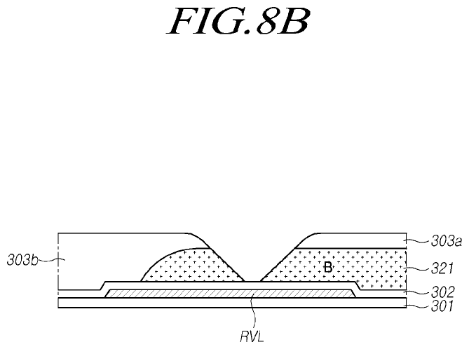

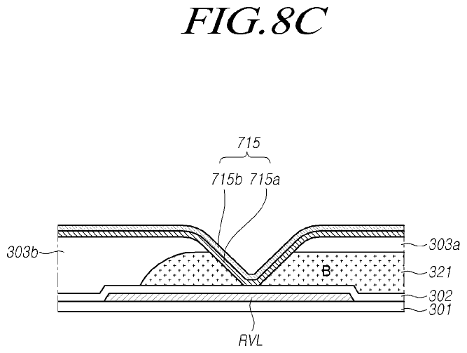

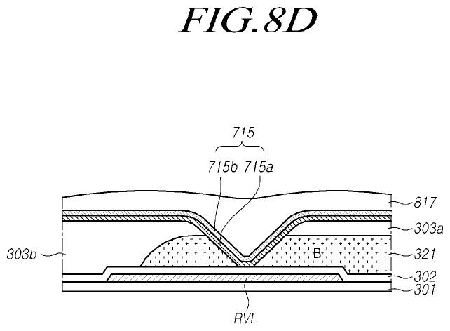

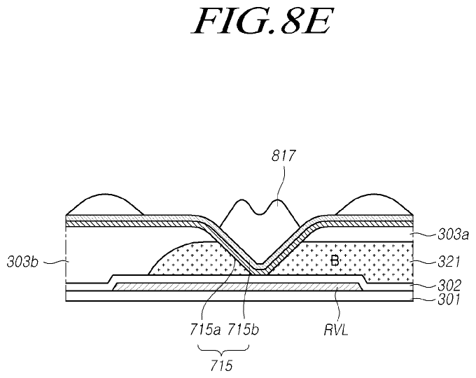

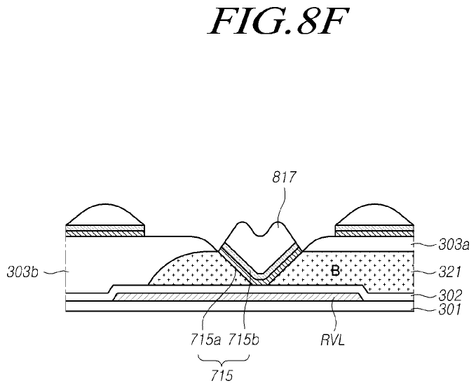

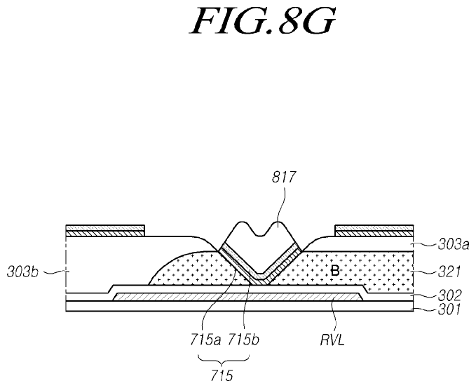

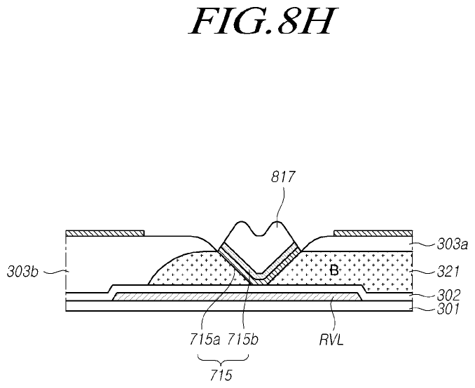

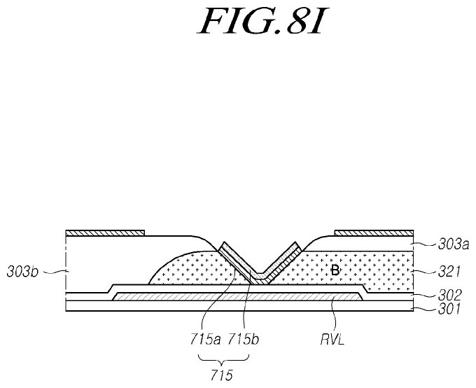

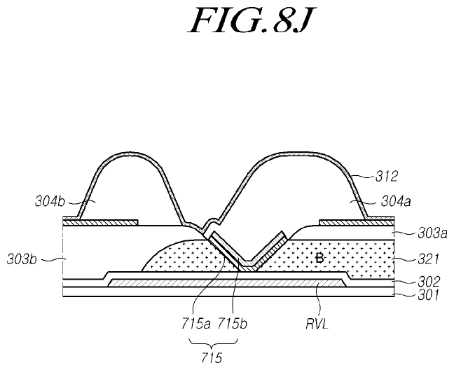

FIG. 6 is a view schematically illustrating a compensation design of an overcoat layer slit according to aspects of the present disclosure. FIGS. 8A, 8B, 8C, 8D, 8E, 8F, 8G, 8H, 8I, and 8J are views illustrating a process of forming a light blocking member on a color filter according to aspects of the present disclosure.

In the display device according to aspects of the present disclosure, after the color filter is formed in the subpixel area constituting the pixel area on the substrate 301, the overcoat layers 303a and 303b are formed on the color filter to be disconnected at the boundary of the subpixel area.

Referring to FIG. 6, the step of forming the overcoat layers 303a and 303b includes forming the overcoat layers 303a and 303b with the halftone transmittance and the spacing of the overcoat slit mask set to reduce to the outside at the edge portion (area E).

The slit structure of the overcoat layers 303a and 303b in the inside (area B) of the substrate 301 and the edge portion (area E) are formed using the same mask over the entire display panel. However, as the thickness of the overcoat layers 303a and 303b at the edge portion (area E) of the display panel is relatively smaller than the thickness of the inside (area B), the slit uniformity of the overcoat layers 303a and 303b may be deteriorated due to the difference in thickness of the overcoat layers 303a and 303b although photolithography and ashing are performed under the same conditions, causing an excessive slit spacing between the overcoat layers 303a and 303b in the edge portion (area E) of the display panel.

In adjusting the spacing of the overcoat slit mask outward at the edge portion (area E) of the substrate 301 in the step of forming the overcoat layers 303a and 303b, the slit mask spacing outward of the edge portion (area E) may be reduced to be 40% to 85% of the slit mask spacing of the inside (area B).

For example, when the slit mask spacing in the inside (area B) is 6.0 μm, the slit of the overcoat layers 303a and 303b may be formed, with E4 to E1 which belong to the edge portion (area E) set to have a spacing reduced to 5.0 μm to 2.5 μm.

Further, in adjusting the halftone transmittance outward at the edge portion (area E) of the substrate 301 in the step of forming the overcoat layers 303a and 303b, the halftone transmittance outward of the edge portion (area E) may be reduced to 40% to 85% of the halftone transmittance of the inside (area B).

For example, when the halftone transmittance of the inside (region B) is 100%, the slit of the overcoat layers 303a and 303b may be formed, with E4 to E1, which belong to the edge portion (region E), set to have a halftone transmittance reduced to 85% to 40%.

Referring to FIGS. 8A to 8J, in the step of forming the overcoat layers 303a and 303b, the color filter is formed to be cut off in the disconnected area between the overcoat layers 303a and 303b by etching the color filter layer opened in the disconnected area between the overcoat layers 303a and 303b.

After cutting off the color filter, a material of a first electrode 311 of the first layer 715b and the second layer 715a is deposited to form the first electrode on the color filter and the overcoat layers 303a and 303b.

The first layer 715b may be formed of a metal-based material, such as Cu, Al, Mo, MoTi, Ag, or Au, and the second layer 715a may be formed of one of ITO, IZO, ITO/APC/ITO, AlNd/ITO, Ag/ITO, and ITO/APC/ITO.

After depositing the material of the first electrode 311, the material of the first electrode 311 is etched and patterned to allow the light blocking member 715 to be positioned in the disconnected area between the overcoat layers 303a and 303b.

After patterning the material of the first electrode 311, a halftone process is performed to leave the second layer 715a on the overcoat layers 303a and 303b, thereby forming the first electrode 311, and to leave the first layer 715b and the second layer 715a in the disconnected area between the overcoat layers 303a and 303b, thereby forming the light blocking member 715.

After forming the first electrode 311, the bank layers 304a and 304b are formed on the boundary between the overcoat layers 303a and 303b and, in the step of forming the bank layers 304a and 304b, the overlapping portion OLP is formed so that the first bank layer 304a in the first subpixel area and the second overcoat layer 303b in the second subpixel area overlap with each other on the color filter.

After the overlapping portion OLP is formed, the light emitting layer 312 and the second electrode (not shown) are formed on the bank layers 304a and 304b and the overcoat layers 303a and 303b, thereby completing the display device.

As the light blocking member 715 is disposed on the color filter, the display device and method for manufacturing the same according to aspects of the present disclosure may prevent the light generated in the blue (B) subpixel area from being reflected by the light blocking member 715 to the white (W) pixel area. As the overlapping portion OLP is positioned on the color filter, the color filter may be completely covered, preventing contact between the light emitting layer 312 and the color filter, with the result of mitigating moisture permeability and dark spots and allowing for uniform viewing angle VF over the entire display panel.

The above description has been presented to enable any person skilled in the art to make and use the technical idea of the present disclosure, and has been provided in the context of a particular application and its requirements. Various modifications, additions and substitutions to the described aspects will be readily apparent to those skilled in the art, and the general principles defined herein may be applied to other aspects and applications without departing from the spirit and scope of the present disclosure. The above description and the accompanying drawings provide an example of the technical idea of the present disclosure for illustrative purposes only. That is, the disclosed aspects are intended to illustrate the scope of the technical idea of the present disclosure.

What is claimed is:

1. A display device, comprising:
a substrate;
a pixel area including two or more subpixels on the substrate, and of the pixel area, a first subpixel area where a color filter is positioned and a second subpixel area adjacent to the first subpixel area are disposed;
a first overcoat layer and a second overcoat layer disconnected between the first subpixel area and the second subpixel area, the first overcoat layer and the second overcoat layer respectively positioned in the first subpixel area and the second subpixel area; and
a first bank layer positioned at a boundary of the first subpixel area and a second bank layer positioned at a boundary of the second subpixel area,
wherein the first bank layer and the second overcoat layer include an overlapping portion where the first bank layer and the second overcoat layer overlap with each other on the color filter.

2. The display device of claim 1, wherein the first bank layer and the second overcoat layer contact each other at the overlapping portion.

3. The display device of claim 1, wherein the disconnected area between the first overcoat layer and the second overcoat layer is positioned in an area of the first bank layer.

4. The display device of claim 1, wherein a boundary of the first bank layer and the second bank layer is positioned in an area of the second overcoat layer.

5. The display device of claim 1, wherein the first subpixel area is one of a red subpixel, a blue subpixel, and a green subpixel.

6. The display device of claim 1, wherein the second subpixel area is a white subpixel.

7. The display device of claim 1, further comprising a light blocking member disposed on the color filter.

8. The display device of claim 7, wherein the light blocking member includes a first electrode.

9. The display device of claim 7, wherein the color filter is disconnected between the first overcoat layer and the second overcoat layer.

10. The display device of claim 9, wherein the light blocking member is positioned in the disconnected area of the color filter.

11. A method for manufacturing a display device, the method comprising:
forming a color filter in a subpixel area constituting a pixel area on a substrate;
forming an overcoat layer on the color filter to be disconnected at a boundary of the subpixel area;
forming a first electrode on the overcoat layer;
forming a bank layer on a boundary of the overcoat layer; and
forming a light emitting layer on the bank layer and the overcoat layer,
wherein the forming the bank layer includes forming an overlapping portion where a first bank layer in a first subpixel area and a second overcoat layer in a second subpixel area overlap with each other on the color filter.

12. The method of claim 11, wherein the forming the overcoat layer includes forming the overcoat layer by reducing an overcoat slit mask spacing or halftone transmittance outward at an edge portion of the substrate.

13. The method of claim 11, wherein the forming the overcoat layer includes etching the color filter to be disconnected in the disconnected area of the overcoat layer.

14. The method of claim 11, wherein the forming the first electrode includes etching and patterning a material of the first electrode to allow a light blocking member to be positioned in the disconnected area of the overcoat layer.
